(19) United States
(12) Patent Application Publication
(10) Pub. No.: US 2024/0120224 A1
(43) Pub. Date: Apr. 11, 2024

(54) SEMICONDUCTOR MANUFACTURING EQUIPMENT, AND METHOD FOR TRANSPORTING REPLACEABLE COMPONENTS IN THE SEMICONDUCTOR MANUFACTURING EQUIPMENT

(71) Applicant: Samsung Electronics Co., Ltd., Suwon-si (KR)

(72) Inventors: Jin Hyuk CHOI, Suwon-si (KR); Beom Soo HWANG, Suwon-si (KR); Kong Woo LEE, Suwon-si (KR); Myung Ki SONG, Suwon-si (KR); Ja-Yul KIM, Suwon-si (KR); Kyu Sang LEE, Suwon-si (KR); Hyun Joo JEON, Suwon-si (KR); Nam Young CHO, Suwon-si (KR)

(73) Assignee: Samsung Electronics Co., Ltd., Suwon-si (KR)

(21) Appl. No.: 18/465,533

(22) Filed: Sep. 12, 2023

(30) Foreign Application Priority Data
Oct. 6, 2022 (KR) 10-2022-0127766

(51) Int. Cl. H01L 21/673; H01L 21/67; H01L 21/677; H01L 21/68

(52) U.S. Cl. CPC H01L 21/67386; H01L 21/67259; H01L 21/67294; H01L 21/67742; H01L 21/68; H01L 21/6833

(57) ABSTRACT

A semiconductor manufacturing equipment may include a process chamber for treating a substrate; a front-end module including a first transfer robot, wherein the first transfer robot may be configured to transport the substrate received in a container; a transfer chamber between the front-end module and the process chamber, wherein the transfer chamber may be configured to load or unload the substrate into or out of the process chamber; and a cassette capable of receiving a replaceable component capable of being used in the process chamber. The front-end module may include a seat plate configured to move in a sliding manner so as to retract or extend into or from the front-end module. The cassette may be configured to be loaded into the front-end module while the cassette is seated on the seat plate.

### CROSS-REFERENCE TO RELATED APPLICATION

This application claims priority from Korean Patent Application No. 10-2022-0127766 filed on Oct. 6, 2022 in the Korean Intellectual Property Office, and all the benefits accruing therefrom under 35 U.S.C. 119, the contents of which in its entirety are herein incorporated by reference.

### BACKGROUND

### Field

The present disclosure relates to semiconductor manufacturing equipment and a method for transporting a replaceable component in the semiconductor manufacturing equipment.

### Description of Related Art

When plasma is used to treat a substrate, a ring assembly, such as a focus ring and an edge ring, may be provided around an electrostatic chuck (ESC) such that plasma ions are concentrated on the substrate to improve etching performance on the substrate, and to limit and/or prevent damage to a side of the electrostatic chuck due to the plasma.

However, as an etching time increases, the focus ring or the edge ring may be eroded. After a certain period of time has elapsed, the focus ring or the edge ring should be replaced. When replacing the focus ring or the edge ring, downtime of an EFEM (Equipment Front-end Module) is necessary. In an access through a transfer module, a separate space for an input chamber may be required, which may increase a footprint.

### SUMMARY

A technical feature of the present disclosure is to provide semiconductor manufacturing equipment in which a replaceable component is provided to a process chamber without the downtime of the EFEM, and to provide a method for transporting the replaceable component in the semiconductor manufacturing equipment.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an example embodiment of the present disclosure, a semiconductor manufacturing equipment may include a process chamber for treating a substrate; a front-end module including a first transfer robot, the first transfer robot being configured to transport the substrate in a container; a transfer chamber between the front-end module and the process chamber, the transfer chamber being configured to load or unload the substrate into or out of the process chamber; and a cassette capable of receiving a replaceable component capable of being used in the process chamber. The front-end module may include a seat plate configured to move in a sliding manner so as to retract or extend into or from the front-end module, and the cassette may be configured to be loaded into the front-end module while the cassette has been seated on the seat plate.

According to an example embodiment of the present disclosure, a semiconductor manufacturing equipment may include a process chamber for treating a substrate; a front-end module including a first transfer robot, the first transfer robot being configured to transport the substrate in a container; a transfer chamber between the front-end module and the process chamber, the transfer chamber being configured to load or unload the substrate into or out of the process chamber; and a cassette capable of receiving a replaceable component capable of being used in the process chamber. The cassette may include a housing, a first shutter on a side face of the housing, a plurality of identification codes for recognizing a position of the first shutter, and a centering structure on an inner face of the first shutter. The housing may define an inner space for receiving the replaceable component. The first shutter may be configured to open or close the inner space of the housing. The identification codes may be on the side face of the housing onto which the first shutter is on. The centering structure may be configured to center the replaceable component in the inner space of the housing when the first shutter is closed. The front-end module may include a seat plate configured to move in a sliding manner so as to retract or extend into or from the front-end module, a second shutter between a first space of the front-end module and a second space of the front-end module, a pair of guides in the second space and adjacent to the second shutter, and an adapter configured for withdrawing the replaceable component out of the cassette. The first transfer robot may be in the first space of the front-end module. The second space of the front-end module may be a region of the front-end module configured for loading the cassette into the front-end module. The pair of guides may be configured to fix a position of the cassette. The cassette may be configured to be loaded into the front-end module while the cassette is seated on the seat plate.

According to an example embodiment of the present disclosure, a semiconductor manufacturing equipment may include a process chamber for treating a substrate; a front-end module including a first transfer robot, the first transfer robot being configured to transport the substrate in a container; a transfer chamber between the front-end module and the process chamber, the transfer chamber being configured to load or unload the substrate into or out of the process chamber; and a cassette capable of receiving a replaceable component capable of being used in the process chamber, wherein the front-end module includes a seat plate configured to move in a sliding manner so as to retract or extend into or from the front-end module, the cassette is configured to be loaded into the front-end module while the cassette is seated on the seat plate, and the front-end module is configured to operate with stopping while the cassette is loaded into the front-end module.

It should be noted that the effects of the present disclosure are not limited to those described above, and other effects of the present disclosure will be apparent from the following description.

### BRIEF DESCRIPTION OF DRAWINGS

The above and other aspects and features of the present disclosure will become more apparent by describing in detail embodiments thereof with reference to the attached drawings, in which:

FIG. 1 is an illustrative top view showing a structure of a cassette into which a replaceable component is mounted.

FIG. 2 is an illustrative bottom view showing the structure of the cassette into which the replaceable component is mounted.

FIG. 3 is an example diagram for illustrating one type of the handle constituting the cassette into which the replaceable component is mounted.

FIG. 4 is an illustrative diagram for illustrating a coupling relationship between the cassette into which the replaceable component is mounted and the seat plate.

FIG. 5 is an illustrative diagram for illustrating an operation principle of the first shutter constituting the cassette into which the replaceable component is mounted.

FIG. 6 is an illustrative diagram for illustrating one arrangement type of the identification codes constituting the cassette into which the replaceable component is mounted.

FIG. 7 is an illustrative diagram for illustrating a role of the centering structure constituting the cassette into which the replaceable component is mounted.

FIG. 8 is a flowchart sequentially showing a method for mounting the replaceable component into the cassette.

FIG. 9 is a first example diagram schematically showing an internal structure of the semiconductor manufacturing equipment including the EFEM and the process chamber.

FIG. 10 is a second example diagram schematically showing an internal structure of the semiconductor manufacturing equipment including the EFEM and the process chamber.

FIG. 11 is a third example diagram schematically showing an internal structure of the semiconductor manufacturing equipment including the EFEM and the process chamber.

FIG. 12 is a flowchart for sequentially illustrating a process of loading the cassette receiving therein the replaceable component into the FEM.

FIG. 13 is a first illustrative diagram for illustrating each of operations of a process in which the cassette receiving therein the replaceable component is loaded into the FEM.

FIG. 14 is a second illustrative diagram for illustrating each of operations of a process in which the cassette receiving therein the replaceable component is loaded into the FEM.

FIG. 15 is a third illustrative diagram for illustrating each of operations of a process in which the cassette receiving therein the replaceable component is loaded into the FEM.

FIG. 16 is a flowchart for sequentially illustrating a process in which the transfer robot pulls out the replaceable component from the cassette introduced into the FEM.

FIG. 17 is a first illustrative diagram for illustrating each of operations of a process in which the transfer robot draws out the replaceable component from the cassette introduced into the FEM.

FIG. 18 is a second illustrative diagram for illustrating each of operations of a process in which the transfer robot draws out the replaceable component from the cassette introduced into the FEM.

FIG. 19 is a third illustrative diagram for illustrating each of operations of a process in which the transfer robot draws out the replaceable component from the cassette introduced into the FEM.

FIG. 20 is a fourth illustrative diagram for illustrating each of operations of a process in which the transfer robot withdraws the replaceable component from the cassette introduced into the FEM.

### DETAILED DESCRIPTION

Hereinafter, embodiments of the present disclosure will be described in detail referring to the accompanying drawings. The same constituent elements on the drawings are denoted by the same reference numerals, and repeated descriptions thereof will be omitted.

The present disclosure relates to a replaceable component transport system and method for automatically replacing a replaceable component applied to semiconductor manufacturing equipment. The replaceable component transport system and method according to embodiments of the present disclosure may be summarized as having following features.

First, when the replaceable component is provided to a process chamber in the semiconductor manufacturing equipment through the EFEM (Equipment Front-end Module), the replaceable component may be provided to the process chamber without stopping the EFEM. That is, automatic replacement of the replaceable component is enabled without opening an inside of the EFEM.

Second, when replacing the replaceable component in the process chamber, a position thereof may be precisely detected and corrected to enable automatic replacement of the replaceable component.

Third, the replaceable component that cannot be provided through a FOUP (Front Opening Unified Pod) may be provided to the process chamber in the semiconductor manufacturing equipment.

Hereinafter, the features of the present disclosure will be described in detail with reference to drawings and the like. First, a cassette into which the replaceable component is mounted will be described.

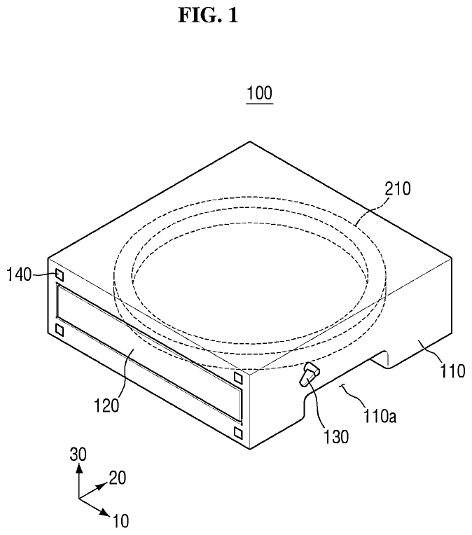

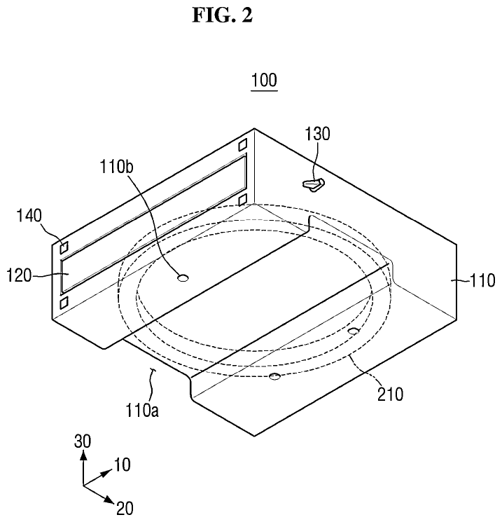

FIG. 1 is an illustrative top view showing a structure of a cassette into which a replaceable component is mounted. FIG. 2 is an illustrative bottom view showing the structure of the cassette into which the replaceable component is mounted. More specifically, FIG. 1 illustrates a drawing which looks down at the cassette 100 from the top, and FIG. 2 illustrates a drawing which looks up at the cassette 100 from the bottom.

According to FIG. 1 and FIG. 2, a cassette 100 into which a replaceable component 210 is mounted may be configured to include a housing 110, a first shutter 120, a shutter opening/closing module 130, and an identification code 140.

The housing 110 has a space defined therein into the replaceable component 210 is mounted. The housing 110 has an inner space therein, so that the replaceable component 210 may be mounted into the inner space of the housing 110. The cassette 100 may be capable of and configured to receive the replaceable component 210 in the housing 110.

The housing 110 may be made of a durable material so that the replaceable component 210 is not deteriorated or damaged by external impact or stress. Further, the housing 110 may be formed in a desired and/or alternatively predetermined shape having the inner space defined therein. For example, the housing 110 may have a rectangular parallelepiped shape. However, the present disclosure is not limited thereto, and the housing 110 may have each of various shapes such as a cube shape, a polygonal prism shape, a cylindrical shape, and an elliptical prism shape. That is, the housing 110 may have any shape as long as the housing has a sufficient inner space into which the replaceable component 210 is mounted. Hereinafter, a case in which the housing 110 has the rectangular parallelepiped shape will be described by way of example.

When the housing 110 is brought into an interior of the EFEM to provide the replaceable component 210 to the process chamber, the housing may be brought into the EFEM while being seated on a seat plate. After the replaceable component 210 is provided to the process chamber, the housing may be unloaded out of the inside of the EFEM while being seated on the seat plate. In this regard, an operator or a working robot may remove the housing 110 from the seat plate to mount a new replaceable component 210 into the housing 110 again. For this purpose, a handle may be formed on the housing 110.

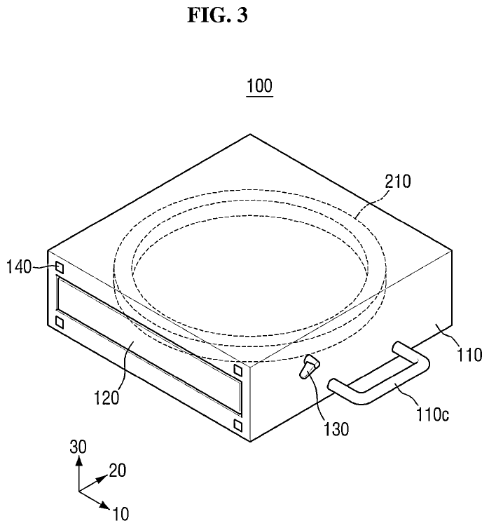

In the example of FIG. 1 and FIG. 2, a first groove 110a extending in a longitudinal direction (first direction) 10 may be formed in a bottom face of the housing 110. The first groove 110a may function as the handle. However, the present embodiment is not limited thereto. As shown in an example of FIG. 3, a protruding member 110c from a side face of the housing 110 in an outward direction may be formed. The protruding member 110c may serve as the handle. FIG. 3 is an example diagram for illustrating one type of the handle constituting the cassette into which the replaceable component is mounted.

In another example, although not shown in FIGS. 1 and 2, a second groove extending in a width direction (second direction 20), that is, a second groove extending in a direction perpendicular to the longitudinal direction of the first groove 110a may be further formed. When the second groove extends in the direction perpendicular to the longitudinal direction of the first groove 110a, the operator may insert a hand into the second groove and may easily pull the housing 110 with a small force.

As described above, the housing 110 may be brought into the EFEM while being seated on the seat plate. The housing 110 may include a seat hole 110b defined in the bottom face thereof so that the housing may be fixed to the seat plate after being seated on the seat plate.

A plurality of seat holes 110b may be defined in the bottom face of the housing 110. For example, three seat holes 110b may be defined in the bottom face of the housing 110 as shown in the example of FIG. 1 and FIG. 2. However, the present embodiment is not limited thereto. A single seat hole 110b may be defined in the bottom face of the housing 110. In another example, the seat hole 110b may be formed in an area of the bottom face of the housing 110 in which the first groove 110a is not formed.

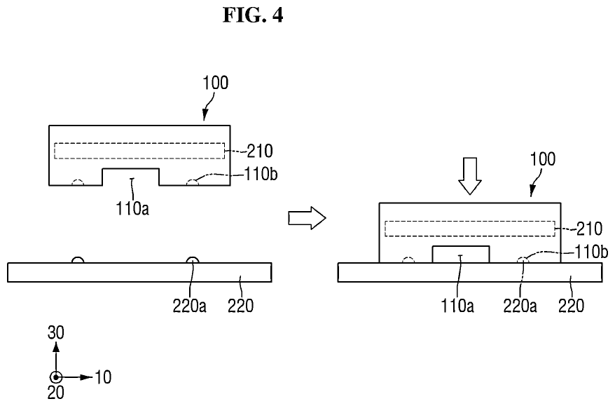

As will be described later, as shown in FIG. 4, a seat pin 220a may be formed on a seat plate 220 on which the housing 110 is seated. The seat pin 220a is inserted into the seat hole 110b. The number of the seat pins 220a may be equal to the number of the seat holes 110b, and a size and a position thereof may correspond to a size and a position of the seat hole 110b. The seat pin 220a may be inserted into the seat hole 110b such that the housing 110 may be fixed to the seat plate 220. FIG. 4 is an illustrative diagram for illustrating a coupling relationship between the cassette into which the replaceable component is mounted and the seat plate.

Referring back to FIG. 1 and FIG. 2 again, description will be made.

The first shutter 120 serves to open and close an inside of the housing 110. As the first shutter 120 opens and closes the inside of the housing 110, a transfer robot in the EFEM may unload the replaceable component 210 out of the inside of the housing 110.

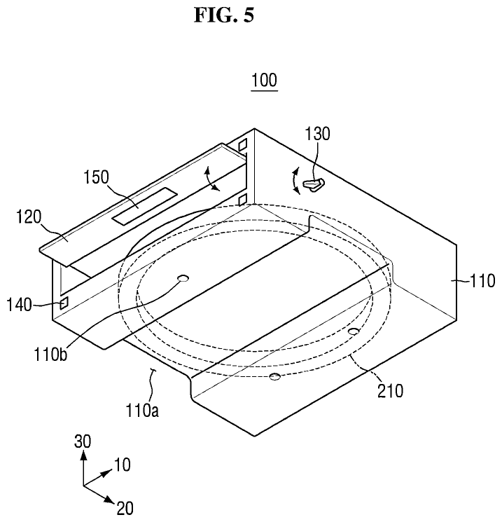

The first shutter 120 may be installed on a side face of the housing 110. The first shutter 120 may be provided in a form of a door, and may pivot as shown in FIG. 5 according to an operation of the shutter opening/closing module 130 to open and close the inside of the housing 110. FIG. 5 is an illustrative diagram for illustrating an operation principle of the first shutter constituting the cassette into which the replaceable component is mounted.

The shutter opening/closing module 130 may be provided in a form of a pivotable lever as the first shutter 120 may be pivotal. However, the present embodiment is not limited thereto. The shutter opening/closing module 130 may be provided in a form of a button, and may open and close the inside of the housing 110 in response to an input thereto.

The shutter opening/closing module 130 may be disposed on a side face of the housing 110 as the first shutter 120 may. In this case, the shutter opening/closing module 130 may be disposed on a different side face of the housing from the side face thereof on which the first shutter 120 is disposed. Further, the shutter opening/closing module 130 may be disposed on a face coplanar with an outer exposed face of the first groove 110a so that the shutter opening/closing module 130 may be manipulated by the operator.

Referring back to FIG. 1 and FIG. 2, description will be made.

The identification code 140 may be provided so that the transfer robot in the EFEM may recognize a position of the cassette 100. Specifically, the identification code 140 may indicate a position of the first shutter 120 so that the transfer robot may unload the replaceable component 210 out of the cassette 100. The identification code 140 may be provided in a form of a QR code. However, the present disclosure is not limited thereto, and any identifiable code such as a barcode may be provided as the identification code 140 in the present embodiment.

The identification codes 140 may be arranged to surround the first shutter 120 while being disposed on a side face of the housing 110 so that the position of the first shutter 120 may be easily recognized. For this purpose, the plurality of identification codes 140 may be disposed on the side face of the housing 110. For example, four identification codes 140 may be arranged as shown in the example in FIG. 1 and FIG. 2.

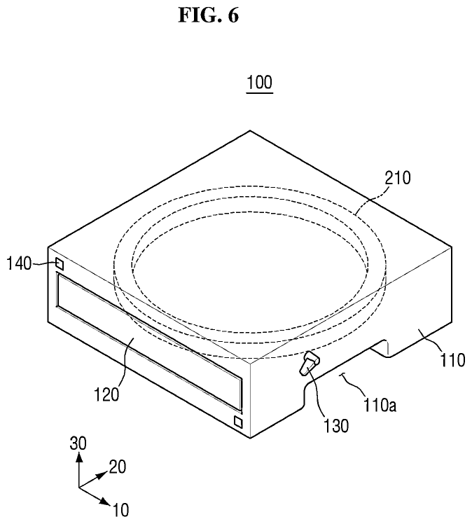

An arrangement of the identification codes 140 may be made such that the transfer robot in the EFEM may easily recognize the position of the first shutter 120. For example, two or three identification codes 140 may be disposed on the side face of the housing 110. When two identification codes 140 are disposed on the side face of the housing 110, the identification codes 140 may be arranged diagonally as shown in FIG. 6. FIG. 6 is an illustrative diagram for illustrating one arrangement type of the identification codes constituting the cassette into which the replaceable component is mounted.

In another example, when three are disposed on the side face of the housing 110, the three identification codes 140 may be selected from the four identification codes 140 in the case where the four identification codes 140 are arranged on the side face of the housing 110, as shown FIG. 3. In another example, when five or more identification codes 140 are disposed on the side face of the housing 110, the five or more identification codes 140 may be arranged based on a combination of the case where two codes are arranged on the side face of the housing 110, the case where three codes are arranged on the side face of the housing 110, and the case where four codes are arranged on the side face of the housing 110.

The following description refers to FIG. 5.

The replaceable component 210 may be automatically centered in the inner space of the housing 110 when the first shutter 120 is closed. Thus, according to the present embodiment, the replaceable component 210 may be precisely and fixedly received in the cassette 100.

The replaceable component 210 refers to a component that may be installed in the semiconductor manufacturing equipment and may need to be replaced after being used for a certain period of time. Hereinafter, an example in which the replaceable component 210 is the focus ring or the edge ring which is installed around an electrostatic chuck (ESC) in an apparatus for treating a substrate (wafer) using plasma will be described.

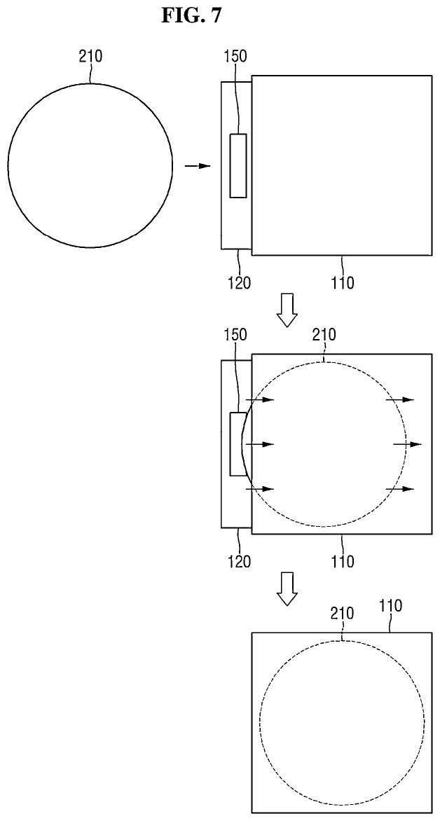

A centering structure 150 for centering the replaceable component 210 may be installed on an inner face of the first shutter 120. As shown in FIG. 7, when the replaceable component 210 is inserted into the inner space of the housing 110, the centering structure 150 may push an outer exposed portion of the replaceable component 210 so that the replaceable component 210 is entirely inserted into the inner space of the housing 110. In this case, the replaceable component 210 may be precisely and fixedly received in the cassette 100 while being in close contact with inner side faces of the housing 110. FIG. 7 is an illustrative diagram for illustrating a role of the centering structure constituting the cassette into which the replaceable component is mounted. The centering structure 150 may be formed to protrude from the surface of the first shutter 120. For example, the centering structure 150 may be provided as a plastic guide.

The cassette 100 into which the replaceable component 210 is mounted has been described above with reference to FIG. 1 to FIG. 7. The cassette 100 includes the first shutter 120 having a self-align structure to allow the replaceable component 210 to be precisely and fixedly received therein. When the first shutter 120 is closed, the replaceable component 210 is self-aligned and fixed, so that a position thereof does not change due to shaking during movement of the cassette.

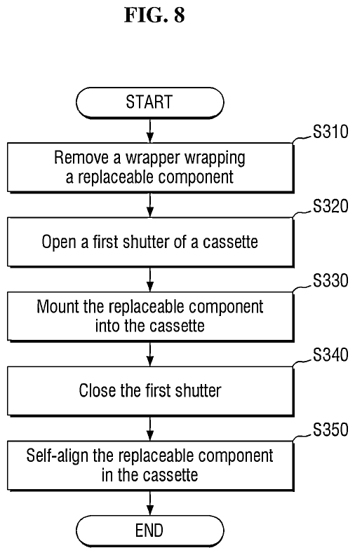

Hereinafter, a method by which the replaceable component 210 is mounted in the cassette 100 will be described. FIG. 8 is a flowchart sequentially showing a method for mounting the replaceable component into the cassette. Following descriptions refer to FIG. 8.

An operation of mounting of the replaceable component 210 into the cassette 100 may be done in a clean booth that guarantees a clean environment. First, a wrapper that wraps the replaceable component 210 is removed in S310. The wrapper may be in a cleaned state before being brought into the clean booth, and may be, for example, made of vinyl.

Thereafter, the operator manipulates the shutter opening/closing module 130 to open the first shutter 120 so that the replaceable component 210 may be mounted in S320. Then, the replaceable component 210 is introduced into the housing 110 through an opening formed when the first shutter 120 is in the open state in S330. Thereafter, the first shutter 120 is closed in S340, and the replaceable component 210 is self-aligned in the inner space of the housing 110 according to action of the centering structure 150 in S350.

As described above, the centering structure 150 for self-aligning the replaceable component 210 is disposed on the inner face of the first shutter 120. Accordingly, the position of the replaceable component 210 may be always maintained to be constant in the cassette 100, and the replaceable component 210 may be fixed during transport of the cassette 100.

In the present embodiment, when the first shutter 120 is closed, the centering structure 150 of the cassette 100 may automatically position the replaceable component 210 to a center of the inner space of the housing 110. Further, the position of the replaceable component 210 may be limited and/or prevented from being changed during movement of the cassette. Further, when the cassette 100 is docked to the EFEM, the cassette may move while a position thereof is not deviated due to a guide mechanism attached to the EFEM.

The replaceable component 210 is mounted into the cassette 100. Then, the cassette 100 into which the replaceable component 210 has been mounted may move to the EFEM so as to be provided to the process chamber in the semiconductor manufacturing equipment. Although described above, in the present embodiment, the replaceable component 210 may be provided to the process chamber without stopping the EFEM. Further, in the present embodiment, the replaceable component 210 may be provided to the process chamber without opening the inside of the EFEM. Hereinafter, this will be described.

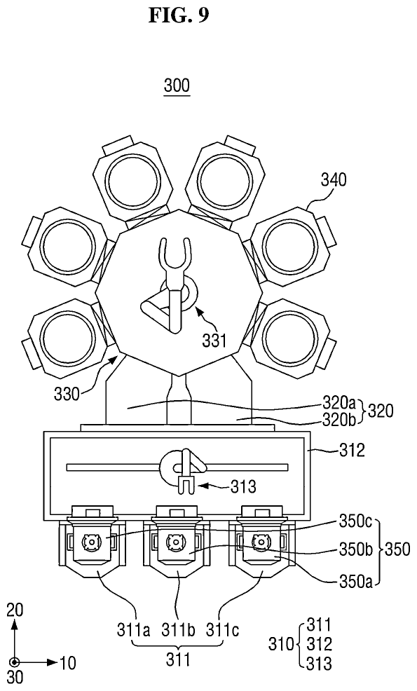

FIG. 9 is a first example diagram schematically showing an internal structure of the semiconductor manufacturing equipment including the EFEM and the process chamber. Following descriptions refer to FIG. 9.

Semiconductor manufacturing equipment 300 serves to treat a semiconductor substrate. The semiconductor manufacturing equipment 300 may include a process chamber 340 which is installed adjacent to a load port 311 so as to treat the semiconductor substrate stored in a container 350. The load port 311 may constitute an end of a front-end module (FEM) 310 such as the EFEM (Equipment Front-end Module), SFEM, etc.

The semiconductor manufacturing equipment 300 may include a plurality of identical or different types of process chambers 340 such as a chamber performing a deposition process, a chamber performing an etching process, a chamber performing a cleaning process, and a chamber performing a heat treatment process. Hereinafter, the semiconductor manufacturing equipment 300 having various arrangement structures will be described.

According to FIG. 9, the semiconductor manufacturing equipment 300 may be configured to include the FEM 310, a load lock chamber 320, a transfer chamber 330 and the process chamber 340. Further, the FEM 310 may be configured to include the load port 311, an indexer 312 and a first transfer robot 313.

The semiconductor manufacturing equipment 300 may be a system that treats the semiconductor substrate through various processes such as the deposition process, the etching process, the cleaning process, and the thermal treatment process. The semiconductor manufacturing equipment 300 may be embodied as a multi-chamber type substrate treatment system including the first transfer robot 313 and a second transfer robot 331 for transporting the substrate, and the plurality of process chambers 340 as a substrate treatment module arranged around the second transfer robot 331.

The load port 311 is constructed such that the container 350 (for example, a FOUP (Front Opening Unified Pod) receiving therein a plurality of semiconductor substrates may be seated thereon. The container 350 may be loaded or unloaded into or out of the load port 311. Further, the semiconductor substrate received in the container 350 may be loaded or unloaded into or out of the load port 311.

In the former case, the container 350 may be loaded or unloaded into or out of the load port 311 by a container transport device (for example, an OHT (Overhead Hoist Transporter)). Specifically, the container transport device may seat the container 350 on the load port 311 such that the container 350 may be loaded into the load port 311. The container transport device may grip the container 350 placed on the load port 311 and then may unload the container 350 out of the load port 311.

In the latter case, the semiconductor substrate may be loaded into or unloaded out of the container 350 seated on the load port 311 by the semiconductor manufacturing equipment 300. When the container 350 is seated on the load port 311, the first transfer robot 313 may approach the load port 311, and thereafter, may take the semiconductor substrate out of the container 350. The unloading of the semiconductor substrate may be done in this process.

Further, when the treatment on the semiconductor substrate in the semiconductor manufacturing equipment 300 is completed, the first transfer robot 313 may take the semiconductor substrate out of the semiconductor manufacturing equipment 300 and put the substrate into the container 350. The loading of the semiconductor substrate may be done in this process.

A plurality of load ports 311 may be disposed in front of the indexer 312. For example, three load ports 311a, 311b, and 311c such as a first load port 311a, a second load port 311b, and a third load port 311c may be disposed in front of the indexer 312.

When the plurality of load ports 311 are arranged in front of the indexer 312, containers 350 respectively seated on the load ports 311 may receive different types of objects. For example, when the three load ports 311 are arranged in front of the indexer 312, a first container 350a seated on the first load port 311a as a left load port may receive therein a wafer-type sensor. A second container 350b seated on the second load port 311b as a middle load port may receive therein the substrate (wafer). A third container 350c seated on a third load port 311c as a right load port may receive therein the focus ring or the edge ring, etc.

However, the present embodiment is not limited thereto. The containers 350a, 350b, and 350c that are seated on the three load ports 311a, 311b, and 311c, respectively may receive therein the same type of objects, respectively. Alternatively, some containers seated on some load ports, respectively may receive therein the same type of objects, respectively, while the other containers seated on the other load ports, respectively may receive therein different types of objects, respectively.

The indexer 312 is disposed between the load port 311 and the load lock chamber 320, and acts as an interface to transport the semiconductor substrate between the container 350 on the load port 311 and the load lock chamber 320. The indexer 312 may be a part of the front-end module (FEM) 310 as described above.

The indexer 312 may include the first transfer robot 313 responsible for transporting the substrate. The first transfer robot 313 may operate in an atmospheric pressure environment, and may transport the semiconductor substrate between the container 350 and the load lock chamber 320.

In another example, although not shown in FIG. 9, at least one buffer chamber may be provided in the indexer 312. An untreated substrate may be temporarily stored in the buffer chamber before being transported to the load lock chamber 320. A treated substrate may be temporarily stored in the buffer chamber before being loaded into the container 350 on the load port 311. The buffer chamber may be disposed on a sidewall not adjacent to the load port 311 or the load lock chamber 320. However, the present disclosure is not limited thereto, and the buffer chamber may be disposed on a sidewall adjacent to the load lock chamber 320.

In one example, in FIG. 9, it is illustrated that the plurality of load ports 311 constituting the FEM 310 are arranged in a horizontal direction. However, the present disclosure is not limited thereto, and the plurality of load ports 311 may be stacked in a vertical direction. That is, in the present embodiment, the FEM 310 may be embodied as, for example, a vertical stack type EFEM.

The load lock chamber 320 may be referred to as a buffer chamber, and may act as a buffer between an input port and an output port on the semiconductor manufacturing equipment 300. Although not shown in FIG. 9, the load lock chamber 320 may include a buffer stage in which the semiconductor substrate temporarily waits.

A plurality of load lock chambers 320 may be disposed between the indexer 312 and the transfer chamber 330. For example, two load lock chambers 320a and 320b such as a first load lock chamber 320a and a second load lock chamber 320b may be disposed between the indexer 312 and the transfer chamber 330.

The first load lock chamber 320a and the second load lock chamber 320b may be disposed between the indexer 312 and the transfer chamber 330 and may be arranged in the first direction 10. In this case, the first load lock chamber 320a and the second load lock chamber 320b may be arranged in a mutually symmetrical single-layer structure in which the first load lock chamber 320a and the second load lock chamber 320b are arranged side by side in a left and right direction. In this regard, the first direction 10 means a direction perpendicular to the second direction 20 as a direction in which the indexer 312 and the transfer chamber 330 are arranged in a plan view.

However, the present embodiment is not limited thereto. The first load lock chamber 320a and the second load lock chamber 320b may be arranged in the third direction 30 while being disposed between the indexer 312 and the transfer chamber 330. In this case, the first load lock chamber 320a and the second load lock chamber 320b may be arranged in a multilayer structure such that the first load lock chamber 320a and the second load lock chamber 320b are arranged in the vertical direction. In this regard, the third direction 30 means a direction perpendicular to a plane defined by the second direction 20 as the arrangement direction of the indexer 312 and the transfer chamber 330 and the first direction 10 perpendicular to the second direction 20 in the plan view.

The first load lock chamber 320a may transport the semiconductor substrate from the indexer 312 to the transfer chamber 330. The second load lock chamber 320b may transport the semiconductor substrate from the transfer chamber 330 to the indexer 312. However, the present embodiment is not limited thereto. The first load lock chamber 320a may serve to transport the substrate from the transfer chamber 330 to the indexer 312, and serve to transport the substrate from the indexer 312 to the transfer chamber 330. Similarly, the second load lock chamber 320b may serve to transport the substrate from the transfer chamber 330 to the indexer 312 and may serve to transport the substrate from the indexer 312 to the transfer chamber 330.

The second transfer robot 331 of the transfer chamber 330 may load or unload the semiconductor substrate into or out of the load lock chamber 320. The first transfer robot 313 of the indexer 312 may load or unload the semiconductor substrate into or out of the load lock chamber 320.

The load lock chamber 320 may maintain a pressure therein while changing an interior thereof to a vacuum environment or an atmospheric pressure environment using a gate valve or the like. Thus, the load lock chamber 320 may limit and/or prevent an internal pressure state of the transfer chamber 330 from being changed.

Specifically, when the substrate is loaded or unloaded by the second transfer robot 331, the inside of the load lock chamber 320 may be brought into a vacuum environment equal to or (approximate to) a vacuum environment of the transfer chamber 330. Further, when the substrate is loaded or unloaded by the first transfer robot 313 (that is, the load lock chamber 320 receives an untreated substrate from the first transfer robot 313 or a treated substrate is transferred from the load lock chamber to the indexer 312), an interior of the load lock chamber 320 may be brought into an atmospheric pressure environment.

The transfer chamber 330 transfers the substrate between the load lock chamber 320 and the process chamber 340. For this purpose, the transfer chamber 330 may include at least one second transfer robot 331.

The second transfer robot 331 transports the untreated substrate from the load lock chamber 320 to the process chamber 340, or transports the treated substrate from the process chamber 340 to the load lock chamber 320. For this purpose, sides of the transfer chamber 330 may be respectively connected to the load lock chamber 320 and the plurality of process chambers 340. In one example, the second transfer robot 331 may operate in the vacuum environment and may freely rotate.

The process chamber 340 is configured to treat the substrate. The plurality of process chambers 340 may be arranged around the transfer chamber 330. In this case, each of the process chambers 340 may receive the semiconductor substrate from the transfer chamber 330 and may treat the semiconductor substrate, and may provide the treated semiconductor substrate to the transfer chamber 330.

Each process chamber 340 may be formed in a cylindrical shape. A surface of the process chamber 340 may be made of alumite as an anodized film. An inside of the process chamber may be sealed. In one example, the process chamber 340 may be formed in a shape other than the cylindrical shape in the present embodiment.

The semiconductor manufacturing equipment 300 may be formed in a structure having a cluster platform. In this case, the plurality of process chambers 340 may be arranged in a cluster manner around the transfer chamber 330, and a plurality of load lock chambers 320 may be arranged in the first direction 10.

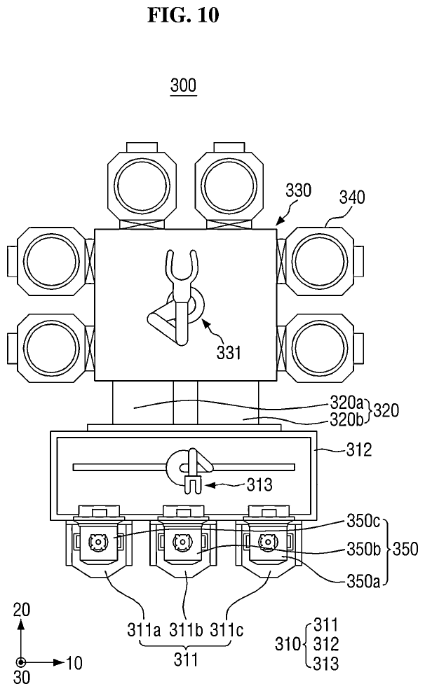

However, the present embodiment is not limited thereto. The semiconductor manufacturing equipment 300 may also be formed in a structure having a quad platform as shown in FIG. 10. In this case, the plurality of process chambers 340 may be arranged in a quad manner around the transfer chamber 330. FIG. 10 is a second example diagram schematically showing an internal structure of the semiconductor manufacturing equipment including the EFEM and the process chamber.

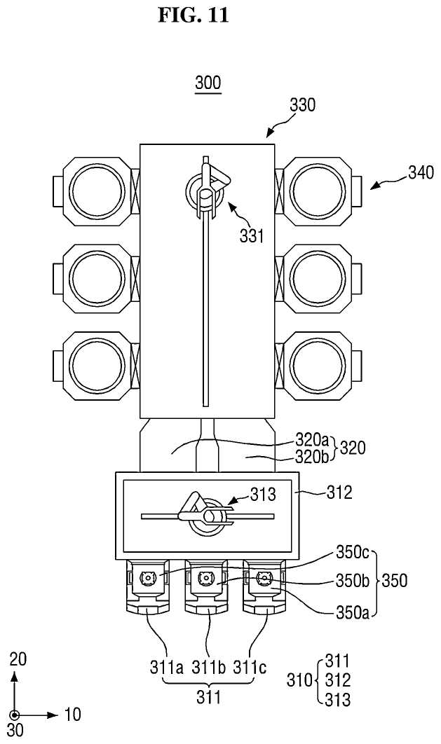

Alternatively, the semiconductor manufacturing equipment 300 may be formed in a structure having an in-line platform as shown in FIG. 11. In this case, the plurality of process chambers 340 may be arranged in an in-line manner. A first group of process chambers 340 may be arranged in an in-line manner and disposed on one of both opposing sides of the transfer chamber 330, while a second group of process chambers 340 may be arranged in an in-line manner and disposed on the other of both opposing sides of the transfer chamber 330. FIG. 11 is a third example diagram schematically showing an internal structure of the semiconductor manufacturing equipment including the EFEM and the process chamber.

Although not shown in FIG. 9, the semiconductor manufacturing equipment 300 may further include a controller. The controller controls an operation of each of modules constituting the semiconductor manufacturing equipment 300. In one example, the controller may control loading and unloading of the substrate by each of the first transfer robot 313 and the second transfer robot 331, and may control a substrate treatment process of the process chamber 340.

The controller may include a process controller embodied as a microprocessor (computer) that controls the semiconductor manufacturing equipment 300, a keyboard on which an operator performs a command input to manage the semiconductor manufacturing equipment 300, a user interface embodied as a display, etc., to visually display an operating status of the semiconductor manufacturing equipment 300, and a storage for storing therein a control program for executing the treatment executed in the semiconductor manufacturing equipment 300 under the control of the process controller, or a program for executing treatment on each component according to various data and treatment conditions, that is, a treatment recipe. Further, the user interface and the storage may be connected to the process controller. The treatment recipe may be stored in a storage medium of the storage. The storage medium may be a hard disk, and may be a portable disk such as CD-ROM or DVD, or a semiconductor memory such as a flash memory.

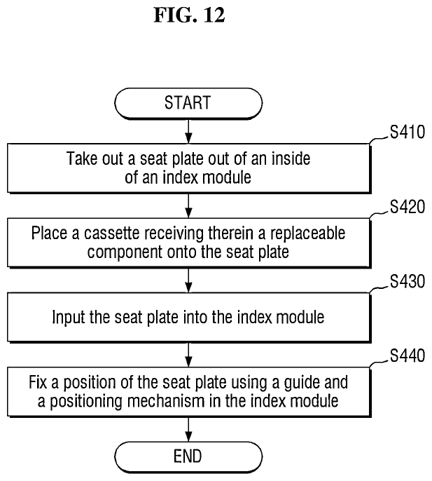

Next, a process of loading the cassette 100 into which the replaceable component 210 has been mounted into the FEM 310 such as the EFEM or SFEM will be described. FIG. 12 is a flowchart for sequentially illustrating a process of loading the cassette receiving therein the replaceable component into the FEM. Following descriptions refer to FIG. 12.

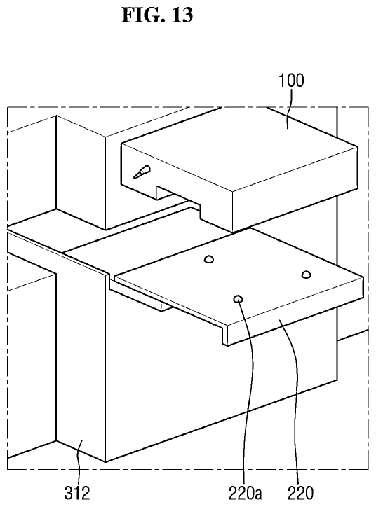

First, the process includes taking out the seat plate 220 out of an inside of the indexer 312 in S410. The seat plate 220 may be provided in a sliding structure so as to slide out of the inside of the indexer 312 to an outside such that the seat plate is exposed outwardly. For example, the seat plate 220 may be constructed to have a sliding structure using an LM guide (Linear Motion guide) including an LM block and an LM rail. The seat plate 220 pulled out from the inside of the indexer 312 is in a state as shown in an example of FIG. 13. FIG. 13 is a first illustrative diagram for illustrating each of operations of a process in which the cassette receiving therein the replaceable component is loaded into the FEM.

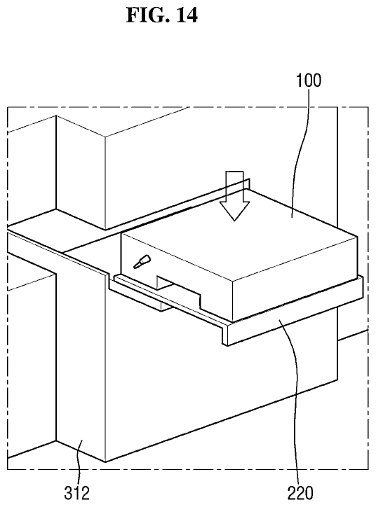

After the seat plate 220 has been withdrawn out of the indexer, the operator or the working robot places the cassette 100 receiving therein the replaceable component 210 onto the seat plate 220 as shown in an example of FIG. 14 in S420. In this case, the seat pin 220a on the seat plate 220 may be inserted into the seat hole 110b defined in the bottom face of the housing 110 of the cassette 100, and thus the cassette 100 may be fixed to the seat plate 220. FIG. 14 is a second illustrative diagram for illustrating each of operations of a process in which the cassette receiving therein the replaceable component is loaded into the FEM.

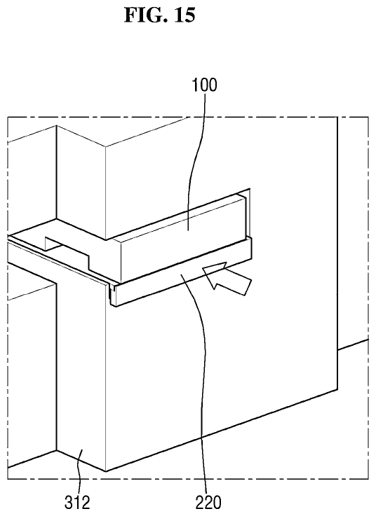

When the cassette 100 has been seated on the seat plate 220, the operator or the working robot pushes the seat plate 220 on which the cassette 100 has been seated into the indexer 312 as shown in an example of FIG. 15 in S430. Although not shown in FIG. 15, a position of the seat plate 220 may be fixed because a guide is disposed on a side thereof in the pushing direction. Further, when the cassette 100 reaches a specific position in the indexer 312, the cassette may be fixed via a positioning mechanism in S440. FIG. 15 is a third illustrative diagram for illustrating each of operations of a process in which the cassette receiving therein the replaceable component is loaded into the FEM.

Because the cassette 100 receiving therein the replaceable component 210 is loaded into the indexer 312 through a rear face of the indexer 312 as described with reference to FIG. 13 to FIG. 15, an effect of not increasing an equipment area regardless of a shape of the FEM 310 such as the vertical stack type EFEM may be obtained.

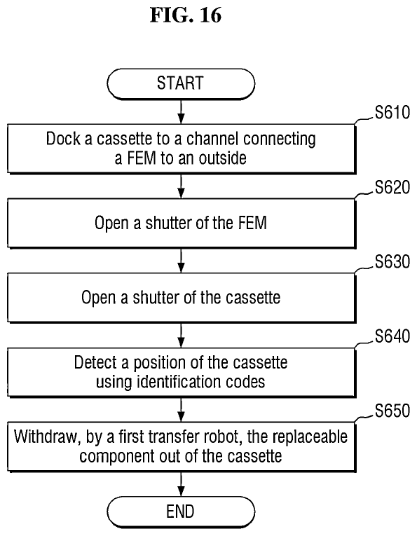

Next, a process in which the first transfer robot 313 of the indexer 312 withdraws the replaceable component 210 out of the cassette 100 loaded into the FEM 310 will be described. FIG. 16 is a flowchart for sequentially illustrating a process in which the transfer robot pulls out the replaceable component from the cassette introduced into the FEM. Following descriptions refer to FIG. 16.

Recently, many schemes have been devised to replace a component inside the process chamber 340 using a vacuum transport robot to extend a PM (Process Module) cycle of the process chamber 340. In this regard, components that may be received into the container 350 together with an adapter may be input into a dedicated FOUP using an arm of the first transfer robot 313 in the FEM 310. However, a component sized such that the component cannot be received into the container 350, for example, an outer ring such as a focus ring or an edge ring may be separately stored inside the FEM 310. Alternatively, a loading chamber isolated with a gate valve may be attached to a side of a TM (Transfer Module) and may be vented and then the outer ring may be input to the loading chamber, and a chamber pressure may be lowered to a vacuum again and then the gate valve may be opened and then the outer ring may be handled.

In order for the outer ring to be stored in the FEM 310, the operator may need to stop the operation of the FEM 310 and open a door of the FEM 310 for component replacement and then manually insert the outer ring into the FEM 310. In order to restart the FEM after the component replacement, an internal environment of the FEM 310 such as a temperature, humidity, and particle amount should be adjusted.

However, according to the present disclosure, the replaceable component 210 may be sized such that the component cannot be received into the container 350 is mounted into the cassette 100, which in turn is attached to an outer side of the FEM 310. Then, the robot in the FEM 310 may adjust a positional precision of the cassette and put the cassette into the FEM. Each of the cassette and the FEM has the shutter. Thus, due to the opening and closing operation of each shutter, the internal environment of the FEM 310 may not be affected. Thus, the operation of the FEM 310 does not stop.

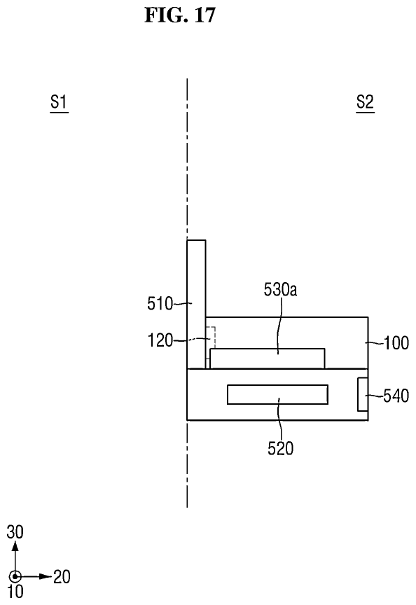

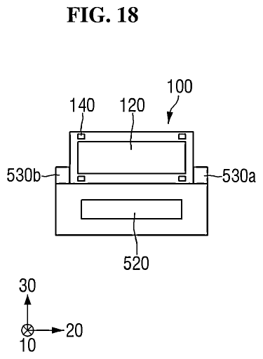

As described above, when the cassette 100 into which the replaceable component 210 has been mounted reaches a specific position in the indexer 312, a position thereof may be fixed by the guide and the positioning mechanism. In this case, as shown in FIG. 17 and FIG. 18, a shutter of the FEM, that is, a second shutter 510 may be installed between a space S1 in the indexer 312 where the first transfer robot 313 is located and a space S2 in the indexer 312 where the cassette 100 is located. According to the opening and closing of the second shutter 510, the first transfer robot 313 may unload the replaceable component 210 therefrom. FIG. 17 is a first illustrative diagram for illustrating each of operations of a process in which the transfer robot draws out the replaceable component from the cassette introduced into the FEM. FIG. 18 is a second illustrative diagram for illustrating each of operations of a process in which the transfer robot draws out the replaceable component from the cassette introduced into the FEM.

The second shutter 510 may extend in the third direction 30 as a height direction of the indexer 312. In this regard, a longitudinal direction of the shutter 510 may be the third direction 30. An adapter 520 may be disposed below the second shutter 510, a pair of guides 530a and 530b may be installed on the adapter 520, and the cassette 100 may be inserted into a space between the both opposing guides 530a and 530b. The adapter 520 is configured to unload the replaceable component 210 out of the cassette 100, and refers to a structure placed on a top of the robot arm for transport of the replaceable component 210. Each of the guides 530a and 530b refers to a structure for securing a precise position of the cassette 100. The second shutter 510 may be a hinged door or gate valve.

When the adapter 520 is able to be mounted into the container 350, there is no need to secure a separate storage space in the indexer 312. However, in the present embodiment, the adapter may act as a support structure for the guides 530a and 530b. The adapter 520 may be fixed at all times, or may be replaced or move through a third shutter 540 disposed on a side of the indexer.

The cassette 100 receiving therein the replaceable component 210 is loaded into the FEM 310 and then a position thereof is fixed by the guides 530a and 530b in the indexer 312. When the cassette 100 is docked to a channel connecting the FEM to the outside, the cassette 100 is positioned on the adapter 520, and the first shutter 120 as the shutter of the cassette is adjacent to the second shutter 510 as the shutter of the FEM in S610.

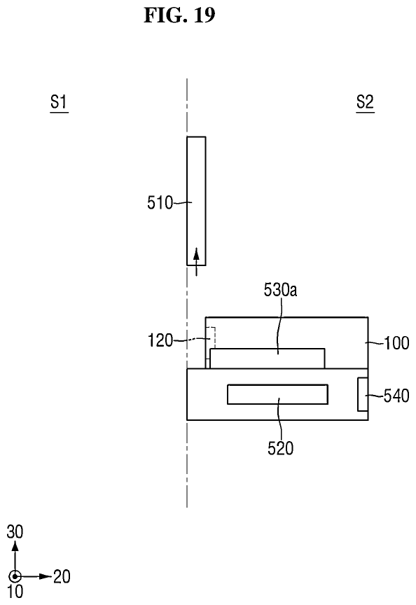

In order that the first transfer robot 313 in the indexer 312 withdraws the replaceable component 210 out of the cassette 100, the second shutter 510 is first opened, as shown in FIG. 19 in S620. In an example of FIG. 19, it is shown that the second shutter 510 operates in a sliding manner. However, the present disclosure is not limited thereto. The second shutter 510 operates in a hinged door manner. FIG. 19 is a third illustrative diagram for illustrating each of operations of a process in which the transfer robot draws out the replaceable component from the cassette introduced into the FEM.

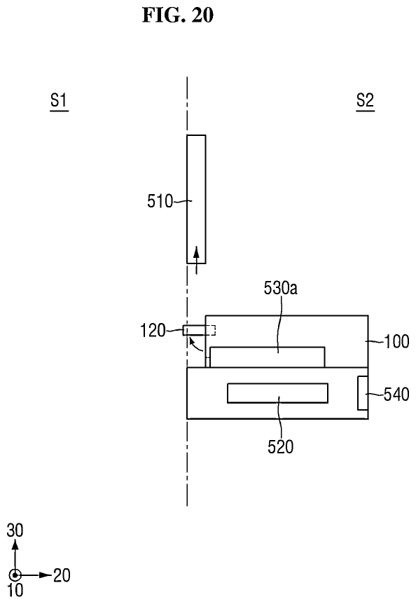

Thereafter, the shutter opening/closing module 130 is manipulated to open the first shutter 120 as shown in FIG. 20 in S630. The manipulation of the shutter opening/closing module 130 to open the first shutter 120 may be performed by the first transfer robot 313. However, the present disclosure is not limited thereto, and the shutter opening/closing module 130 may be manipulated under an operation of a motor according to an input signal. FIG. 20 is a fourth illustrative diagram for illustrating each of operations of a process in which the transfer robot withdraws the replaceable component from the cassette introduced into the FEM.

Then, the first transfer robot 313 detects the position of the cassette 100 in S640. The first transfer robot 313 may detect the plurality of identification codes 140 attached to the side face of the cassette 100 in order to detect the position of the cassette 100, and may automatically determine the position of the cassette 100 based on a recognizing result of the plurality of identification codes 140.

The first transfer robot 313 may be equipped with an identification code sensor on a side face of the arm or hand thereof in order to recognize the identification code 140. The identification code sensor may be embodied as a QR code reader when the identification code 140 is embodied as a QR code. The identification code sensor may be attached to any position of the first transfer robot 313 as long as the identification code sensor may effectively detect the identification code 140 attached to the side face of the cassette 100. The identification code sensor may include a camera that detects the identification code 140 (e.g., 140) and provides a signal or data corresponding to an image or data of the identification code 140 to processing circuitry that identifies the identification code 140 based on the signal or data corresponding to the image or data of the identification code 140.

When the first transfer robot 313 recognizes a position of a side face opened via the movement of the first shutter 120, based on the detection of the identification code 140, the first transfer robot 313 unloads the replaceable component 210 out of the housing 110 using the arm and the hand thereof in S650. The first transfer robot 313 may identify a position of the replaceable component 210 and then automatically correct the position thereof and then may input the replaceable component 210 into the load lock chamber 320.

As described above with reference to FIG. 12 to FIG. 20, the cassette 100 is loaded into the indexer 312 while the replaceable component 210 has been mounted into the cassette. When the second shutter 510 and the first shutter 120 are opened, the first transfer robot 313 unloads the replaceable component 210 out of the cassette 100. Thus, the replaceable component 210 may be input into the FEM 310 without shutting down the FEM 310. Further, in accordance with the present embodiment, an effect of inputting the replaceable component 210 into the FEM 310 without opening the inside of the FEM 310 may be achieved.

After the replaceable component 210 has been transported to the indexer 312 by the first transfer robot 313, the replaceable component 210 may be transferred to the process chamber 340 in the same way as the untreated substrate unloaded from the container 350 may be transferred. That is, the second transfer robot 331 may supply the replaceable component 210 to the inside of the process chamber 340 through the load lock chamber 320 and the transfer chamber 330 in this order. Accordingly, in accordance with the present embodiment, the replaceable component 210 may be provided to the process chamber 340 without stopping the FEM 310, and the replaceable component 210 may be provided to the process chamber 340 without opening the inside of the FEM 310.

For example, when the first transfer robot 313 unloads the replaceable component 210 out of the cassette 100 and transfers the replaceable component 210 to the load lock chamber 320, picking up the outer ring, retracting the arm, lowering the arm to a vertical level of the load lock chamber (320), moving the arm to an input position to the load lock chamber (320), inserting the outer ring into the load lock chamber (320), and retracting the arm, and returning the arm may be sequentially carried out.

In the outer ring pickup operation, the adapter capable of picking up the outer ring may be mounted on the arm of the first transfer robot 313, and the outer ring may be picked up based on the position identified based on the identification code 140. In this regard, the adapter may be pre-placed in the FEM 310 or be taken from the container 350.

Further, for automatic replacement of the outer ring, the second transfer robot 331 takes out a used outer ring from the process chamber 340 and provides the used outer ring to the load lock chamber 320, and then takes out an unused outer ring from the load lock chamber 320 and provides the unused outer ring to the process chamber 340. In this case, the used outer ring may be loaded onto the cassette 100 by the first transfer robot 313 and then unloaded to the outside.

When the replaceable component 210 is input into the process chamber 340 and then the replaceable component 210 is installed therein, the position of the replaceable component 210 may be detected using the wafer-type sensor in which a camera module is installed and may be corrected. Further, whether the replaceable component 210 is normally installed may be verified using the wafer-type sensor. In installing the replaceable component 210, wafer centering detection and correction may be employed. Thus, according to the present embodiment, a positional precision of the replaceable component 210 may be automatically detected and corrected, and the replaceable component 210 may be input based on the corrected position thereof. The positional accuracy of the replaceable component 210 may be identified by the wafer-type sensor input into the process chamber. In some embodiments, if the replaceable component 210 is abnormally installed into the process chamber 340, a robotic arm may be inserted into the process chamber 340 to correct a position of the replaceable component 210. If the position of the replaceable component 210 cannot be corrected using the robotic arm, then the process chamber 340 may be opened to access the inside of the process chamber 340 and correct the position of the replaceable component 210.

In accordance with the present disclosure, as described above, the replaceable component 210 may be supplied to the process chamber 340 without stopping the FEM 310, and the automatic replacement of the replaceable component 210 may be achieved without opening the inside of the FEM 310. When the replaceable component 210 such as the outer ring may be replaced in the process chamber 340 without breaking the vacuum, an equipment operation time may be increased, which may also improve productivity of semiconductors.

Although not illustrated, operations of the semiconductor manufacturing equipment according to example embodiments may be controlled by a controller. The controller may include processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The controller may operate in response to control signals, commands, and/or instructions input thereto from an external source (e.g., host). The controller may execute instructions stored in a memory for controlling operations of the semiconductor manufacturing according to example embodiments described herein.

While some example embodiments of the present disclosure have been described above with reference to the accompanying drawings, inventive concepts may be implemented in various different forms. Those skilled in the art to which the present disclosure pertains may understand that embodiments of inventive concepts may be implemented in other specific forms without departing from the spirit and scope of inventive concepts. Therefore, it should be understood that the example embodiments described above are illustrative in all aspects and not restrictive.

What is claimed is:

1. A semiconductor manufacturing equipment comprising:
a process chamber for treating a substrate;
a front-end module including a first transfer robot, the first transfer robot being configured to transport the substrate in a container;
a transfer chamber between the front-end module and the process chamber, the transfer chamber being configured to load or unload the substrate into or out of the process chamber; and
a cassette capable of receiving a replaceable component capable of being used in the process chamber, wherein
the front-end module includes a seat plate configured to move in a sliding manner so as to retract or extend into or from the front-end module, and
the cassette is configured to be loaded into the front-end module while the cassette is seated on the seat plate.

2. The semiconductor manufacturing equipment of claim 1, wherein the front-end module is configured to operate without stopping while the cassette is loaded into the front-end module.

3. The semiconductor manufacturing equipment of claim 1, wherein
the cassette includes a housing, a first shutter on a side face of the housing, and a centering structure on an inner face of the first shutter,
the housing defines an inner space for receiving the replaceable component,
the first shutter is configured to open or close to expose or cover the inner space of the housing,
the centering structure is configured to center the replaceable component in the inner space of the housing.

4. The semiconductor manufacturing equipment of claim 3, wherein the centering structure is constructed to center the replaceable component in the inner space of the housing when the first shutter has been closed.

5. The semiconductor manufacturing equipment of claim 3, wherein
the cassette further includes a plurality of identification codes for recognizing a position of the first shutter, and
the identification codes are installed on the side face of the housing onto which the first shutter is on.

6. The semiconductor manufacturing equipment of claim 5, wherein the identification codes surround the first shutter.

7. The semiconductor manufacturing equipment of claim 5, wherein the first transfer robot includes a sensor for sensing the identification codes.

8. The semiconductor manufacturing equipment of claim 1, wherein
the front-end module further includes a second shutter between a first space of the front-end module and a second space of the front-end module,
the first transfer robot is in the first space of the front-end module, and
the second space of the front-end module is a region of the front-end module configured for loading the cassette into the front-end module, and
the first transfer robot is configured to withdraws the replaceable component out of the cassette when the second shutter is in an open state.

9. The semiconductor manufacturing equipment of claim 8, wherein
the front-end module further includes a pair of guides in the second space,
the pair of guides are adjacent to the second shutter, and
the pair of guides are configured fix a position of the cassette.

10. The semiconductor manufacturing equipment of claim 9, wherein
the front-end module further includes an adapter configured for withdrawing the replaceable component out of the cassette,
the adapter is in the second space and under the second shutter and the pair of guides, or
the adapter is in the second space and on an arm of the first transfer robot.

11. The semiconductor manufacturing equipment of claim 1, wherein a width of the replaceable component is larger than a width of the substrate.

12. The semiconductor manufacturing equipment of claim 11, wherein the replaceable component is an outer ring for surrounding an electrostatic chuck.

13. The semiconductor manufacturing equipment of claim 1, wherein
the semiconductor manufacturing equipment, when the replaceable component is replaced in the process chamber, is configured to detect a position of the replaceable component using a wafer-type sensor and correct the position of the replaceable component.

14. A semiconductor manufacturing equipment comprising:
a process chamber for treating a substrate;
a front-end module including a first transfer robot, the first transfer robot being configured to transport the substrate in a container;
a transfer chamber between the front-end module and the process chamber, the transfer chamber being configured to load or unload the substrate into or out of the process chamber; and
a cassette capable of receiving a replaceable component capable of being used in the process chamber, wherein
the cassette includes a housing, a first shutter on a side face of the housing, a plurality of identification codes for recognizing a position of the first shutter, and a centering structure on an inner face of the first shutter,
the housing defines an inner space for receiving the replaceable component,
the first shutter is configured to open or close the inner space of the housing,
the identification codes are the side face of the housing onto which the first shutter is on; and
the centering structure is configured to center the replaceable component in the inner space of the housing when the first shutter is closed,
the front-end module includes a seat plate configured to move in a sliding manner so as to retract or extend into or from the front-end module, a second shutter between a first space of the front-end module and a second space of the front-end module, a pair of guides in the second space and adjacent to the second shutter, and an adapter configured for withdrawing the replaceable component out of the cassette,
the first transfer robot is in the first space of the front-end module,
the second space of the front-end module is a region of the front-end module configured for loading the cassette into the front-end module,
the pair of guides are configured to fix a position of the cassette,
the cassette is configured to be loaded into the front-end module while the cassette is seated on the seat plate.

15. A semiconductor manufacturing equipment comprising:
a process chamber for treating a substrate;
a front-end module including a first transfer robot, the first transfer robot being configured to transport the substrate in a container;
a transfer chamber between the front-end module and the process chamber, the transfer chamber being configured to load or unload the substrate into or out of the process chamber; and
a cassette capable of receiving a replaceable component capable of being used in the process chamber, wherein
the front-end module includes a seat plate configured to move in a sliding manner so as to retract or extend into or from the front-end module,
the cassette is configured to be loaded into the front-end module while the cassette is seated on the seat plate, and
the front-end module is configured to operate without stopping while the cassette is loaded into the front-end module.

16. The semiconductor manufacturing equipment of claim 15, wherein
the cassette includes a housing, a first shutter on a side face of the housing, and a centering structure on an inner face of the first shutter,
the housing defines an inner space for receiving the replaceable component,
the first shutter is configured to open or close to expose or cover the inner space of the housing,
the centering structure is configured to center the replaceable component in the inner space of the housing, and
the centering structure is constructed to center the replaceable component in the inner space of the housing when the first shutter has been closed.

17. The semiconductor manufacturing equipment of claim 16, wherein
the cassette further includes a plurality of identification codes for recognizing a position of the first shutter, and
the identification codes are installed on the side face of the housing onto which the first shutter is on, and
the identification codes surround the first shutter.

18. The semiconductor manufacturing equipment of claim 15, wherein
the front-end module further includes a second shutter installed between a first space of the front-end module and a second space of the front-end module,
the first transfer robot is in the first space of the front-end module, and
the second space of the front-end module is a region of the front-end module configured for loading the cassette into the front-end module, and
the first transfer robot is configured to withdraws the replaceable component out of the cassette when the second shutter is in an open state.

19. The semiconductor manufacturing equipment of claim 18, wherein
the front-end module further includes a pair of guides and an adapter,
the pair of guides are adjacent to the second shutter in the second space, and are configured fix a position of the cassette, and
the adapter configured for withdrawing the replaceable component out of the cassette.

20. The semiconductor manufacturing equipment of claim 15, wherein
the semiconductor manufacturing equipment, when the replaceable component is replaced in the process chamber, is configured to detect a position of the replaceable component using a wafer-type sensor and correct the position of the replaceable component.
